(19) United States
(12) Patent Application Publication
(10) Pub. No.: US 2008/0237853 A1
(43) Pub. Date: Oct. 2, 2008

(54) SEMICONDUCTOR DEVICE AND MANUFACTURING METHOD OF THE SAME

(75) Inventors: Yoshimasa AMATATSU, Gunma (JP); Minoru AKAISHI, Gunma (JP); Satoshi ONAI, Gunma (JP); Katsuya OKABE, Gunma (JP); Yoshiaki SANO, Tochigi (JP); Akira YAMANE, Gunma (JP)

Correspondence Address: MORRISON & FOERSTER LLP, 1650 TYSONS BOULEVARD, SUITE 400, MCLEAN, VA, 22102, US

(73) Assignees: SANYO Electric Co., Ltd., Moriguchi-shi (JP); SANYO Semiconductor Co., Ltd., Ora-gun (JP)

(21) Appl. No.: 12/056,751

(22) Filed: Mar. 27, 2008

(30) Foreign Application Priority Data
Mar. 27, 2007 (JP) 2007-082434

(51) Int. Cl. H01L 23/48; H01L 21/44

(52) U.S. Cl. 257/737; 438/614; 257/E23.01; 257/E21.476

(57) ABSTRACT

A conventional semiconductor device has a problem that reduction of a resistance value above a pad electrode is difficult because of an oxide film formed on a surface of the pad electrode. In a semiconductor device of this invention, an oxidation preventing metal layer is formed on a pad electrode, and the oxidation preventing metal layer is exposed at an opening region formed in a spin coat resin film at a portion above the pad electrode. In addition, a plating metal layer and a copper plated layer are formed on the oxidation preventing metal layer. With this structure, the resistance value above the pad electrode is reduced because the top surface of the pad electrode is difficult to oxidize, and the oxidation preventing metal layer having considerably smaller sheet resistivity than an oxidation film serves as part of a current path.

This application claims priority from Japanese Patent Application Number JP 2007-082434 filed on Mar. 27, 2007, the content of which is incorporated herein by reference in its entirety.

### BACKGROUND OF THE INVENTION

1. Field of the Invention

The present invention relates to a semiconductor device for reducing a resistance value in a pad electrode formation region and a manufacturing method of the semiconductor device.

2. Description of the Related Art

As an example of a conventional manufacturing method of a semiconductor device, the following manufacturing method, shown in FIGS. 7A to 7F, has been known. As shown in FIG. 7A, an interlayer insulating film 32 made of silicon dioxide or the like is formed on a surface of a silicon substrate 31. Next, as shown in FIG. 7B, an aluminum (Al) electrode pad 33 with a thickness of approximately 1.0 (μm) is formed on the interlayer insulating film 32. Then, as shown in FIG. 7C, a silicon nitride film 34 is formed on the interlayer insulating film 32 including the Al electrode pad 33 as well by a chemical vapor deposition (CVD) method. Subsequently, as shown in FIG. 7D, an opening portion 35 is formed in the silicon nitride film 34 formed on the Al electrode pad 33. Thereafter, as shown in FIG. 7E, a barrier metal film 36 is formed so as to coat the Al electrode pad 33 exposed at the opening portion 35. Finally, as shown in FIG. 7F, a gold bump 37 is formed on the barrier metal film 36 by electrolytic plating. (This technology is described for instance in Japanese Patent Application Publication No. Hei 11-145171, pp. 2-3 and FIG. 1.)

As described above, in the conventional manufacturing method of a semiconductor device, the Al electrode pad 33 is formed on the interlayer insulating film 32, and thereafter, the silicon nitride film 34 serving as a passivation film is formed on the Al electrode pad 33. Subsequently, after the opening portion 35 is formed in the silicon nitride film 34 on the Al electrode pad 33, the barrier metal film 36 is formed on the exposed portion of the Al electrode pad 33 by a sputtering method. In this manufacturing method, in the step of forming the opening portion 35 in the silicon nitride film 34 and thereafter forming the barrier metal film 36, the Al electrode pad 33 exposed at the opening portion 35 is oxidized, and thereby, an oxide film is formed on the Al electrode pad 33. Consequently, a current path above the Al electrode pad 33 is formed so that an electric current flows through the Al electrode pad 33, the oxide film formed on the Al electrode pad 33, the barrier metal film 36 and then the gold bump 37. In this configuration, the oxide film is formed in the current path, and this leads to a problem that reduction of a resistance value above the Al electrode pad 33 is difficult.

### SUMMARY OF THE INVENTION

The present invention has been made in consideration of the above-described circumstances. A semiconductor device according to the present invention is characterized by including: a pad electrode provided on an insulated semiconductor substrate; an oxidation preventing metal layer formed to coat at least a principal surface of the pad electrode; a spin coat resin film formed to coat the oxidation preventing metal layer; an opening region provided in the spin coat resin film to expose the a surface of the oxidation preventing metal layer; a plating metal layer connected to the oxidation preventing metal layer exposed at the opening region of the spin coat resin film; and an electrode formed on the plating metal layer. Accordingly, in this invention, the amount of the oxide film on the one principal surface of the pad electrode provided in the opening region is considerably reduced by the oxidation preventing metal layer. Consequently, the resistance value above the pad electrode is reduced.

### BRIEF DESCRIPTION OF THE DRAWINGS

FIGS. 1A and 1B are cross-sectional views for explaining a semiconductor device according to an embodiment of the present invention.

FIG. 2A is a view for explaining resistance values above a pad electrode, and FIG. 2B is a plan view for explaining a structure on the pad electrode, of the semiconductor device according to the embodiment of the present invention.

FIG. 3 is a cross-sectional view for explaining a manufacturing method of the semiconductor device according to the embodiment of the present invention.

FIG. 4 is a cross-sectional view for explaining the manufacturing method of the semiconductor device according to the embodiment of the present invention.

FIG. 5 is a cross-sectional view for explaining the manufacturing method of the semiconductor device according to the embodiment of the present invention.

FIG. 6 is a cross-sectional view for explaining the manufacturing method of the semiconductor device according to the embodiment of the present invention.

FIGS. 7A to 7F are cross-sectional views for explaining a conventional manufacturing method of a semiconductor device.

### DESCRIPTION OF THE INVENTIONS

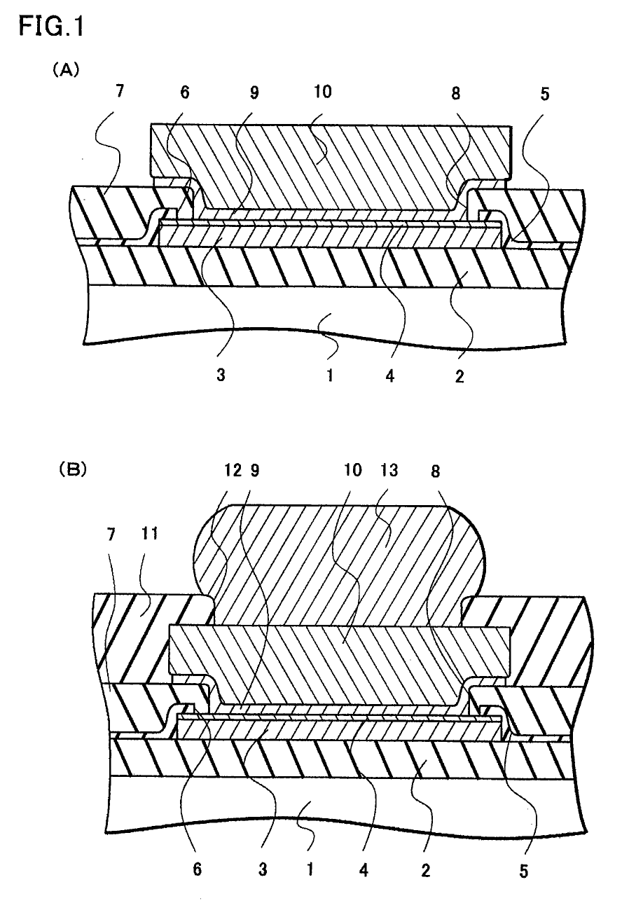

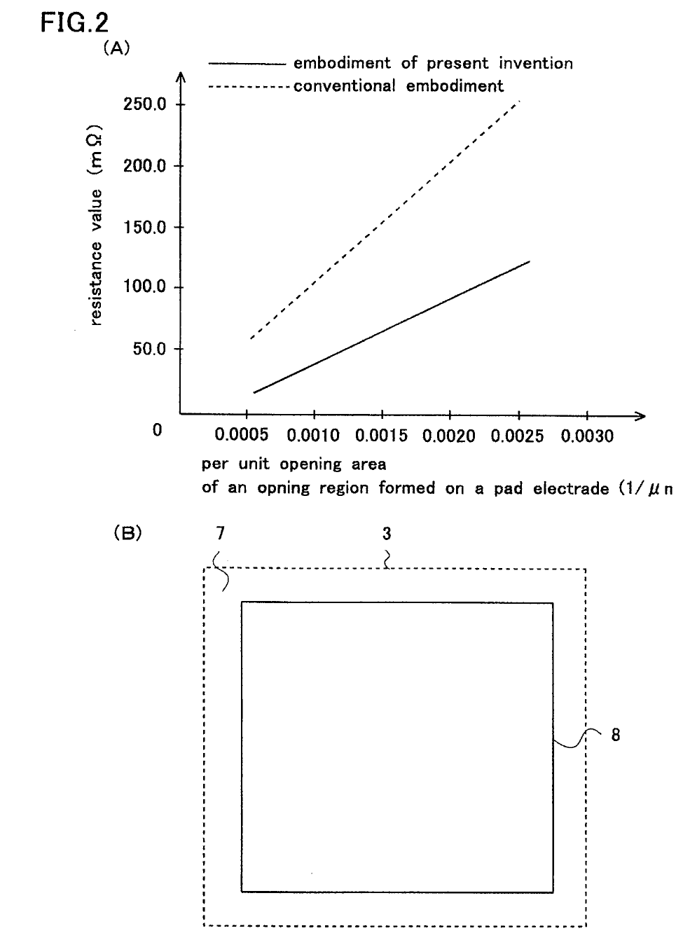

With reference to FIGS. 1A and 1B, and FIGS. 2A and 2B, a semiconductor device according to an embodiment of the present invention will be below described in detail. FIG. 1A is a cross-sectional view for explaining the semiconductor device of this embodiment. FIG. 1B is another cross-sectional view for explaining the semiconductor device of this embodiment. FIG. 2A is a view for explaining resistance values between a pad electrode and a plated layer immediately above the pad electrode of the semiconductor device of this embodiment. FIG. 2B is a plan view for explaining a structure on the pad electrode of the semiconductor device according to this embodiment.

As shown in FIG. 1A, an insulating layer 2 is formed on a silicon substrate 1. The insulating layer 2 is formed of at least one layer selected from a silicon oxide film, a nondoped silicate glass (NSG) film and a boron phospho silicate glass (BPSG) film, for example. Here, by the formation of the insulating layer 2 on the silicon substrate 1, the top surface of the silicon substrate 1 is insulated. Moreover, a single crystal substrate or an epitaxial layer formed on a single crystal substrate can be used as the silicon substrate 1. Alternatively, the silicon substrate 1 may be a compound semiconductor substrate.

A pad electrode 3 formed on the top surface of the insulating layer 2 is made of an alloy layer consisting mainly of aluminum (Al). The pad electrode 3 is formed of an aluminum (Al) layer or an alloy layer consisting mainly of Al such as an aluminum-silicon (Al—Si) film, an aluminum-silicon-copper (Al—Si—Cu) film or an aluminum-copper (Al—Cu) film, for example. The film thickness of the pad electrode 3 is, for example, 0.4 to 3.0 (μm).

Subsequently, an oxidation preventing metal layer 4 is formed on the top surface of the pad electrode 3. The oxidation preventing metal layer 4 is formed of a refractory metal layer such as a titanium nitride (TiN) layer or a titanium tungsten (TiW) layer, for example. The reductive action of the oxidation preventing metal layer 4 makes a natural oxide film difficult to be formed on the top surface of the oxidation preventing metal layer 4. The oxidation preventing metal layer 4 may be used as a reflection preventing layer for an interconnection layer.

Then, a shield layer 5 is formed on the top surface of the insulating layer 2 and parts of the oxidation preventing metal layer 4. The shield layer 5 is formed of a silicon nitride (SiN) film. The shield layer 5 prevents ingress of water to the insulating layer 2, and also prevents corrosion of the interconnection layer and the like. In the formation region of the pad electrode 3, the shield layer 5 formed on the formation region of the pad electrode 3 is removed to form an opening portion 6. The oxidation preventing metal layer 4 is exposed at the opening portion 6.

Subsequently, a spin coat resin film 7 is formed on the top surface of the shield layer 5. The spin coat resin film 7 is an insulating layer such as a polybenzoxazole (PBO) film or a polyimide resin film, for example. The PBO film is photosensitive resin, and has properties such as high heat resistance, a high mechanical property and a low dielectric property. In addition, the PBO film prevents deterioration of semiconductor device caused by the external environment, for example, moisture, and thereby stabilizes the surface of the semiconductor device.

An opening region 8 is formed in the spin coat resin film 7. The formation of the opening region 8 in the spin coat resin film 7 is performed by using a photolithography technique such as wet etching. The opening region 8 is formed in a portion of the spin coat resin film 7, the portion being above the pad electrode 3, and the oxidation preventing metal layer 4 is exposed at the opening region 8.

Then, a plating metal layer 9 is formed on the top surface of the spin coat resin film 7 including the inner surfaces of the opening region 8 as well. In the opening region 8, the plating metal layer 9 is formed on the top surface of the oxidation preventing metal layer 4.

Two types of films are stacked to form the plating metal layer 9. A first film is a refractory metal layer formed of, for example, a chrome (Cr) layer, a titanium (Ti) layer, or titanium tungsten (TiW) layer, and is formed by a sputtering method. The first film is used as a seed layer for forming a plated layer on the plating metal layer 9. Moreover, on the first film, a Cu layer or a nickel (Ni) layer is formed as a second film by a sputtering method, for example. The second film is used as seed for forming a plated layer on the plating metal layer 9. In a case where the PBO film is used as the spin coat resin film 7, for example, by using a Cr layer as the plating metal layer 9, the adhesion between the PBO film and a Cu plated layer 10 is improved because of the adhesion between the PBO film and the Cr layer, and the adhesion between the Cr layer and the Cu plated layer 10.

Subsequently, the Cu plated layer 10 is formed on the top surface of the plating metal layer 9 by, for example, electrolytic plating. When the Cu plated layer 10 is to be formed, the Cu layer is used as the plating metal layer 9.

Meanwhile, when an Au plated layer, instead of the Cu plated layer 10, is to be formed, an Ni layer, instead of the Cu layer, is used as the plating metal layer 9.

Note that, FIG. 1A shows the case where the Cu layer is formed as the plating metal layer 9 and the Cu plated layer 10 is formed on the top surface of the Cu layer. Since the Cu layer formed as the plating metal layer 9 is practically substituted by the Cu plated layer 10 by electrolytic plating, the Cu layer is integrally shown with the Cu plated layer 10 in FIG. 1A. In addition, instead of the Cu plated layer 10, a bump electrode made of, for example, Au or solder may be formed on the plating metal layer 9.

FIG. 1B shows a structure in which the bump electrode is formed in the structure shown in FIG. 1A. Accordingly, the same structure members are denoted by the same reference numerals. Only different structure members are explained, and the explanation for the same structure members is omitted.

As shown in FIG. 1B, a PBO film 11 is first formed on the surface of the structure shown in FIG. 1A. Subsequently, an opening portion 12 is formed in the PBO film 11 formed on the Cu plated layer 10, a part of which is exposed at an opening portion 12.

Next, a bump electrode 13 is formed in connection with the Cu plated layer 10 through the opening portion 12. The bump electrode 13 is formed of, for example, Cu, Au, and solder in this order from the lower layer.

In the structure shown in FIG. 1B, the Cu plated layer 10 may be used as an interconnection layer which electrically connects the Cu plated layer 10 and the formation region of a semiconductor element. Thus, the use of the Cu interconnection layer reduces an interconnection resistivity compared to the case where an Al interconnection layer is used. Specifically, the sheet resistivities of the Cu interconnection layer and the Al interconnection layer are approximately 2.0 (μΩ·cm) and 3.0 (μΩ·cm), respectively. Moreover, the Cu plated layer 10 as the interconnection layer is formed to have a film thickness of approximately 10.0 (μm), by electrolytic plating. Meanwhile, the Al interconnection layer is formed to have a film thickness of approximately 2.0 to 3.0 (μm), by a sputtering method. In sum, by using the Cu plated layer 10 as the interconnection layer, the interconnection resistivity is reduced also because of the film thickness.

Note that, although FIG. 1B shows the case where the opening portion 12 is formed above the formation region of the pad electrode 3, the present invention is not limited to this. As described above, the Cu plated layer 10 may be used as the interconnection layer, and installed in a desired area as long as the Cu plated layer 10 can be connected to the bump electrode. In this case, the interconnection resistivity is reduced by using the Cu interconnection layer, instead of the Al interconnection layer, as the Cu plated layer 10.

FIG. 2A shows resistance values between the pad electrode and the plated layer immediately above the pad electrode when an electric current of, for example, 100 (mA) per unit area of the opening region (called unit opening area, below) formed above the pad electrode 3 is applied. The solid line indicates the resistance values per unit opening area of this embodiment. The dotted line indicates the resistance values per unit opening area of a conventional embodiment. In FIG. 2A, the resistance values in the case where a single opening region is formed on the insulating layer formed above the pad electrode are compared.

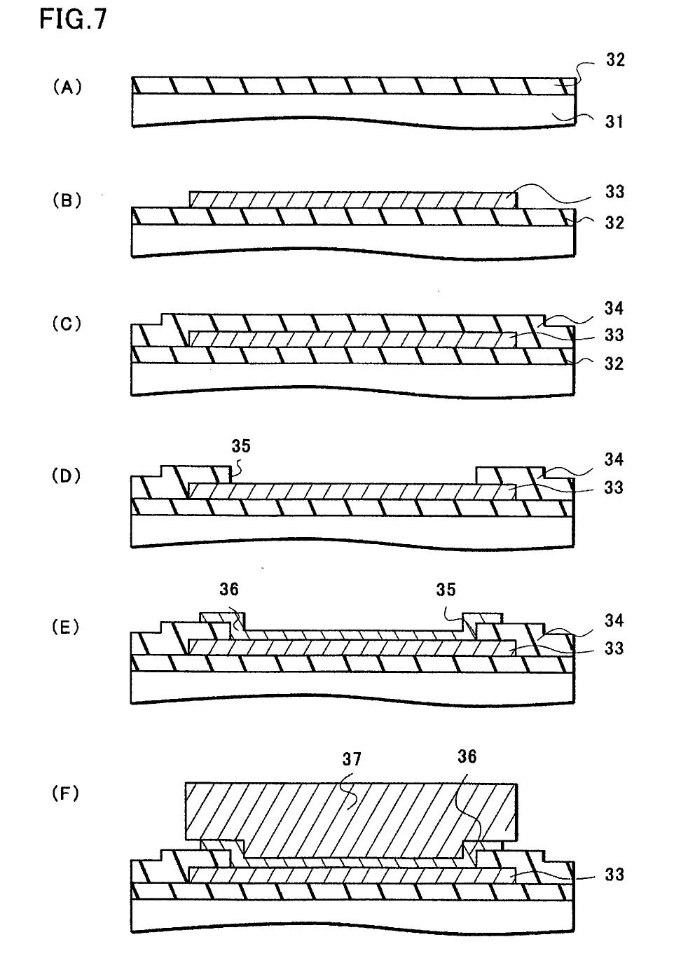

Specifically, the solid line indicates the resistance values per unit opening area of the structure which is formed by stacking the oxidation preventing metal layer 4, the plating metal layer 9 and the Cu plated layer 10 on the pad electrode 3 as shown in FIG. 1A. Meanwhile, the dotted line indicates the resistance values per unit opening area of the structure which is formed by stacking the barrier metal film 36 and the Cu plated layer on the pad electrode 33 as shown in FIG. 7F. Note that, the Au bump 37 is formed on the barrier metal film 36 in FIG. 7F, but the dotted line in FIG. 2A indicates the structure in which the Au bump 37 is substituted by a Cu plated layer with the same film thickness as the solid line case. In addition, the data are shown in FIG. 2A by assuming that the plating metal layer 9 of the solid line case and the barrier metal film 36 of the dotted line case are same in film thickness.

In FIG. 2A, the horizontal line corresponds to an inverse of the surface area of the opening area, and the vertical line corresponds to a resistance per unit area of the opening area. As the solid line indicates, for example, when the unit opening area is 0.0006 (1/μm²), i.e., the opening area is 1600 μm², the resistance value is 19.7 (mΩ). When the unit opening area is 0.0011 (1/μm²), the resistance value is 37.3 (mΩ). When the unit opening area is 0.0025 (1/μm²), the resistance value is 111.2 (mΩ). As the dotted line indicates, for example, when the unit opening area is 0.0006 (1/μm²), the resistance value is 59.7 (mΩ). When the unit opening area is 0.0011 (1/μm²), the resistance value is 121.7 (mΩ). When the unit opening area is 0.0025 (1/μm²), the resistance value is 250.4 (mΩ). By comparing the both structures, the followings are found. When the unit opening area is 0.0006 (1μm²), the resistance value is reduced by approximately 33(%). When the unit opening area is 0.0011 (1/μm²), the resistance value is reduced by approximately 31(%). When the unit opening area is 0.0025 (1/μm²), the resistance value is reduced by approximately 44(%).

As shown in FIG. 1A, in the structure indicated by the solid line, the oxidation preventing metal layer 4 is additionally provided on the pad electrode 3 as compared to the structure indicated by the dotted line. However, the amount of the oxide film on the top surface of the pad electrode 3 is considerably reduced, and thus, the resistance value above the pad electrode 3 is reduced, in the structure indicated by the solid line with respect to the structure indicated by the dotted line.

Here, although the detail will be described later, the opening portion 6 is formed in the shield layer 5 formed above the pad electrode 3 and the opening region 8 is formed in the spin coat resin film 7 in the state where the oxidation preventing metal layer 4 is formed on the pad electrode 3, in the structure of the solid line. In this structure, the oxide film on the top surface of the pad electrode 3 is not practically formed, or is thinly formed. Furthermore, the oxide film is thinly formed on the top surface of the oxidation preventing metal layer 4 as described above. Thus, the top surface of the pad electrode 3 is coated with the oxidation preventing metal layer 4 which have considerably small sheet resistivity compared to the oxide film, and which is difficult to be oxidized. Consequently, the resistance value above the pad electrode 3 is reduced.

Moreover, in FIG. 2B, the dotted line indicates the formation region of the pad electrode 3, and the solid line indicates the opening region 8 formed in the spin coat resin film 7. As shown in FIG. 2B, although the opening region 8 is smaller than the formation region of the pad electrode 3, the opening region 8 is formed to have a large opening region above the pad electrode 3. In this structure, the amount of the oxide film on the top surface of the pad electrode 3 is small, and the region coated with the oxidation preventing metal layer 4 having the small sheet resistivity, i.e. the current path, is increased. Consequently, the resistance value above the pad electrode 3 is reduced. Note that, since the oxidation preventing metal layer 4 coats the top surface of the pad electrode 3, only the oxidation preventing metal layer 4 is exposed at the opening region 8.

Note that, although the case where the oxidation preventing metal layer 4 is exposed at the opening region 8 formed in the spin coat resin film 7 is described in this embodiment, the present invention is not limited to this. For example, the pad electrode 3 as well as the oxidation preventing metal layer 4 may be exposed at the opening region 8 formed in the spin coat resin film 7. In other words, since the electric current mainly flows the region where the resistance value is small, the structure only needs to include the oxidation preventing metal layer 4 provided in the current path above the pad electrode 3 to prevent the oxidation of the top surface of the pad electrode 3. Various other modifications can also be made without departing from the scope of the present invention.

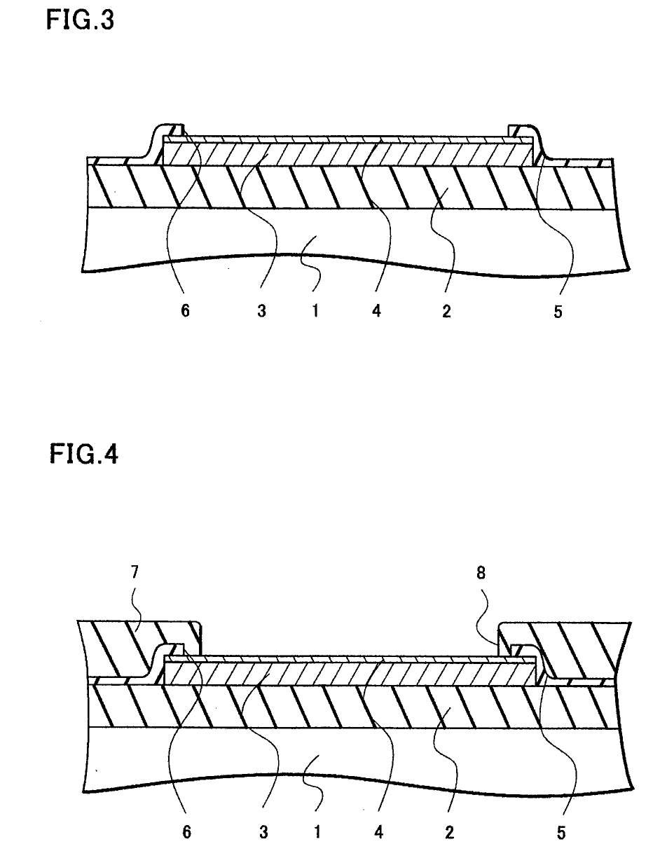

Next, with reference to FIGS. 3 to 6, a manufacturing method of a semiconductor device according to an embodiment of the present invention will be described in detail. FIGS. 3 to 6 are cross-sectional views for explaining the manufacturing method of the semiconductor device of this embodiment. Since the manufacturing method of the structure shown in FIG. 1A will be described, the same structure members are denoted by the same reference numerals.

First, as shown in FIG. 3, a silicon substrate (wafer) 1 is prepared, and an insulating layer 2 is formed on the silicon substrate 1. As the silicon substrate 1, a single crystal substrate or an epitaxial layer formed on a single crystal substrate can be used. Alternatively, the silicon substrate 1 may be a compound semiconductor substrate. As might be expected, a semiconductor element is formed of the diffusion region on the silicon substrate 1 (including the epitaxial layer when an epitaxial layer is formed). Moreover, the insulating layer 2 is formed of at least one layer selected from a silicon dioxide film, an NSG film and a BPSG film, for example. The insulating layer 2 is formed by, for example, a thermal oxidation method or a CVD method.

Subsequently, a pad electrode 3 and an oxidation preventing metal layer 4 are formed on the insulating layer 2. Specifically, on the silicon substrate 1, an Al layer or an alloy layer consisting mainly of Al such as an Al—Si film, an Al—Si—Cu film or an Al—Cu film is deposited by a sputtering method. Thereafter, a TiN layer or TiW layer is deposited directly on the above-described Al layer or the Al alloy layer by, for example, the sputtering method. The Al layer or the Al alloy layer and the TiN layer or the TiW layer are selectively removed by a photolithography technique and an etching technique in order to form the pad electrode 3 and the oxidation preventing metal layer 4. Through the continuous sputtering, the oxidation preventing metal layer 4 is formed on the top surface of the pad electrode 3. Consequently, the oxidation of the top surface of the pad electrode 3 can be prevented.

In the step of forming the pad electrode 3, an interconnection layer may be formed in other region, so that the above-described TiN layer or the TiW layer can be used as a reflection prevention film in the interconnection layer.

Thereafter, an SiN film is deposited on the silicon substrate 1 by, for example, a plasma CVD method. Then, the opening portion 6 is formed in a portion of the SiN film by using the photolithography technique and the etching technique, the portion being above the pad electrode 3, and then, the shield layer 5 is formed. Here, when the opening portion 6 is formed in the SiN film, the oxidation preventing metal layer 4 remains on the top surface of the pad electrode 3 by performing dry etching using, for example, Ar, CF₄, CHF₃, or N₂ system gas. Note that, a resin film such as polyimide may be used instead of this SiN film or the like.

Next, as shown in FIG. 4, a spin coat resin film 7 is formed above the silicon substrate 1 by using, for example, a spin-coating method. As the material, a PBO film, a polyimide resin film or the like is used. Subsequently, an opening region 8 is formed in the spin coat resin film 7 formed above the pad electrode 3 by using the photolithography technique and the etching technique. Then, the oxidation preventing metal layer 4 is exposed at the opening region 8.

Here, in this embodiment, the oxidation preventing metal layer 4 is exposed at the opening portion 6 and at the opening region 8 respectively in the steps of forming the opening portion 6 in the shield layer 5 and of forming the opening region 8 in the spin coat resin film 7. Accordingly, an oxide film formation on the top surface of the pad electrode 3 on which the opening portion 6 and the opening region 8 are provided can be prevented in the both steps. Moreover, since the oxidation preventing metal layer 4 is formed of a TiN layer or a TiW layer, the oxide film is difficult to form on the top surface of the oxidation preventing metal layer 4. Alternatively, the oxide film is thinly formed on the oxidation preventing metal layer 4. In other words, the resistance value above the pad electrode 3 can be reduced by forming the opening portion 6 and the opening region 8 while the top surface of the pad electrode 3 is being coated with the oxidation preventing metal layer 4.

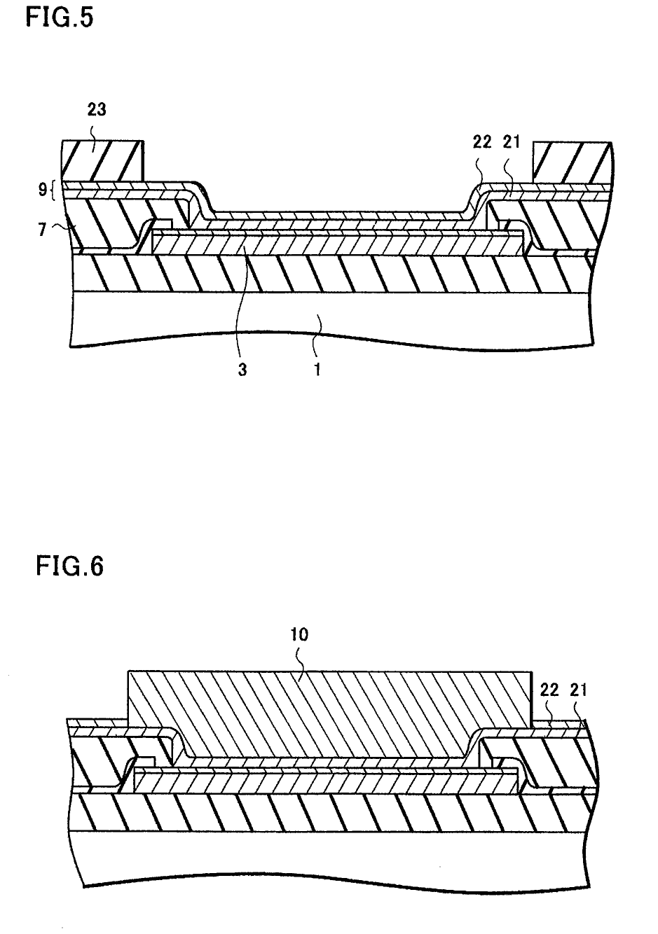

Next, as shown in FIG. 5, a Cr layer 21 and a Cu layer 22 are deposited entirely on the surface of the silicon substrate 1 by, for example, the sputtering method. By using the Cr layer 21 as the plating metal layer 9, the adhesion between the PBO film and a Cu plated layer 10 (see FIG. 6) improves.

Subsequently, here, a photoresist layer 23 is formed except the region where the Cu plated layer 10 is to be formed to pattern the Cu plated layer 10 for lift-off.

Thereafter, as shown in FIG. 6, the Cu plated layer 10 is formed by electrolytic plating. As described above, the Cr layer 21 is used as a seed layer, and the Cu layer 22 is used as seed for electrolytic plating.

Then, the Cu plated layer 10 on the Cr layer 21 and the Cu layer 22 is patterned by removing the above-described photoresist layer 23. Furthermore, the Cr layer 21 and the Cu layer 22 are selectively removed by wet etching using the Cu plated layer 10 as a mask. This completes the structure shown in FIG. 1A. Note that, although not illustrated, the structure may be formed into the one shown in FIG. 1B by further forming the bump electrode 13.

Note that, although the Cu plated layer 10 is formed on the plating metal layer 9, the Cu layer 22 is practically substituted by the Cu plated layer 10 by electrolytic plating. For this reason, the Cu layer is integrally shown with the Cu plated layer, and only the Cr layer 21 is shown.

In this embodiment, described is the case of preparing the wafer, and of then forming, on the wafer, the insulating layer 2, the pad electrode 3, the oxidation preventing metal layer 4, the shield layer 5, the spin coat resin film 7, the plating metal layer 9 and the Cu plated layer 10. However, the present invention is not limited to the case. For example, the wafer on which the insulating layer 2, the pad electrode 3, the oxidation preventing metal layer 4 and the shield layer 5 are formed is prepared, and the spin coat resin film 7, the plating metal layer 9, the Cu plated layer 10, the bump electrode 13 and the like may be formed.

In this embodiment, also described is the case of depositing the Cu layer 22 on the Cr layer 21 as the plating metal layer 9, but the present invention is not limited to the case. For example, as the plating metal layer 9, a Ti layer or a TiW layer may be used instead of the Cr layer 21, and an Ni layer may be formed instead of the Cu layer 22. When a Ni layer is used, an Au plated layer instead of the Cu plated layer may be formed on the Ni layer. Various other modifications can also be made without departing from the scope of the present invention.

In this invention, the formation of the oxidation preventing metal layer on the top surface of the pad electrode considerably reduces the amount of the oxide film on the top surface of the pad electrode. With this structure, the amount of the oxide film is considerably reduced in the current path above the pad electrode, and thus, the resistance value above the pad electrode is reduced.

In addition, in this invention, the oxidation preventing metal layer is formed of a metal layer which is difficult to be oxidized. With this structure, the amounts of the oxide film on top surface of the pad electrode and the top surface of the oxidation preventing metal layer are considerably reduced.

Moreover, in this invention, the use of a chrome layer as the plating metal layer improves the adhesion between the polybenzoxazole film and the electrode.

Furthermore, in this invention, the use of the polybenzoxazole film or the polyimide resin film prevents the deterioration of the semiconductor device caused by the external environment such as moisture.

Additionally, in this invention, the opening region is formed in the spin coat resin film formed above the pad electrode in the state where the oxidation preventing metal layer is formed on the top surface of the pad electrode. With this manufacturing method, the amount of the oxide film on a portion of the pad electrode is reduced, the portion being at the opening region. Consequently, the resistance value above the pad electrode is reduced.

Furthermore, in this invention, the amount of the oxide film on the pad electrode is considerably reduced by depositing the oxidation preventing metal layer directly on a metal layer composing the pad electrode and then selectively removing the both metal layers.

What is claimed is:

1. A semiconductor device comprising:
a pad electrode disposed on a semiconductor substrate;
an oxidation preventing metal layer disposed on the pad electrode so as to be in contact with the pad electrode;
a resin film disposed on the semiconductor substrate and having an opening above the oxidation preventing metal layer;
a plating metal layer disposed in the opening of the resin film so as to be in contact with the oxidation preventing metal layer; and
an electrode disposed on the plating metal layer.

2. The semiconductor device of claim 1, wherein the oxidation preventing metal layer comprises titanium nitride or titanium tungsten.

3. The semiconductor device of claim 1 or 2, wherein the plating metal layer comprises chromium, and the electrode comprises a copper layer and a bump electrode formed on the copper layer.

4. The semiconductor device of claim 3, wherein the resin film comprises polybenzoxazole or polyimide.

5. A method of manufacturing a semiconductor device, comprising:
forming an insulation film on a semiconductor substrate;
forming a pad electrode on the insulation film;
forming an oxidation preventing metal layer on the pad electrode;
spin coating the semiconductor substrate having the oxidation preventing metal layer thereon with a resin so as to form a resin film on the semiconductor substrate;
forming an opening in the resin film to expose part of the oxidation preventing metal layer;
forming a plating metal layer in the opening of the resin film so as to be in contact with the exposed part of the oxidation preventing metal layer; and
forming an electrode on the plating metal layer.

6. The method of claim 5, wherein the formation of the pad electrode comprises forming a first metal layer on the semiconductor substrate, and the formation of the oxidation preventing metal layer comprises forming a second metal layer on the first metal layer and removing portions of the first and second metal layers in the same process to form the oxidation preventing metal layer.

7. The method of claim 5 or 6, wherein the oxidation preventing metal layer comprises titanium nitride layer or titanium tungsten.

8. The method of claim 5 or 6, wherein the plating metal layer comprises chromium, and the formation of the electrode comprises forming a copper layer and forming a bump electrode on the copper layer.

9. The method of claim 8, wherein the resin comprises polybenzoxazole or polyimide.

10. A method of manufacturing a semiconductor device, comprising:
providing a semiconductor wafer comprising a pad electrode formed thereon and an oxidation preventing metal layer formed on the pad electrode;
spin coating the semiconductor wafer having the oxidation preventing metal layer thereon with a resin so as to form a resin film on the semiconductor wafer;
forming an opening in the resin film to expose part of the oxidation preventing metal layer;
forming a plating metal layer in the opening of the resin film so as to be in contact with the exposed part of the oxidation preventing metal layer; and
forming an electrode on the plating metal layer.

11. The method of claim 10, wherein the plating metal layer comprises chromium, and the formation of the electrode comprises forming a copper layer and forming a bump electrode on the copper layer.

12. The method of claim 10 or 11, wherein the resin comprises polybenzoxazole or polyimide.
